(19) United States
(12) Patent Application Publication
(10) Pub. No.: US 2022/0115356 A1
(43) Pub. Date: Apr. 14, 2022

(54) FAN-OUT ENCAPSULATION STRUCTURE AND ENCAPSULATION METHOD FOR CHIP

(71) Applicant: NATIONAL CENTER FOR ADVANCED PACKAGING CO., LTD., Wuxi (CN)

(72) Inventors: Peng SUN, Wuxi (CN); Yulong REN, Wuxi (CN); Liqiang CAO, Wuxi (CN)

(73) Assignee: NATIONAL CENTER FOR ADVANCED PACKAGING CO., LTD., Wuxi (CN)

(21) Appl. No.: 17/416,273

(22) PCT Filed: Oct. 8, 2019
(86) PCT No.: PCT/CN2019/109980

§ 371 Date: Jun. 18, 2021

(30) Foreign Application Priority Data
Dec. 20, 2018 (CN) 2018115652769

(51) Int. Cl. H01L 25/065; H01L 23/00; H01L 23/31; H01L 23/538; H01L 21/683; H01L 21/48; H01L 21/56; H01L 25/00

(52) U.S. Cl. CPC H01L 25/0657; H01L 2221/6835; H01L 23/3128; H01L 23/5383; H01L 23/5386; H01L 21/6835; H01L 21/4853; H01L 21/4857; H01L 21/565; H01L 21/568; H01L 25/50; H01L 2225/0651; H01L 2225/06524; H01L 2225/06568; H01L 2225/06586; H01L 2224/214; H01L 24/20

(57) ABSTRACT

The present application discloses a fan-out packaging structure and a packaging method for a chip. The structure includes first and second chips with oppositely fitted bottoms; metal terminals distributed around the first chip, one side of the metal terminals being on a same plane with the front of the first chip; a lead connected between the front of the second chip and the other side of the metal terminal; a packaging layer for packaging the first chip, the second chip, the lead the metal terminals; and a lead-out layer disposed on a first surface of the packaging layer and electrically connected to one side of the metal terminals and/or the front of the first chip.

### TECHNICAL FIELD

The present application relates to the technical field of semiconductor packaging, in particular to a fan-out type packaging structure and a packaging method for a chip.

### BACKGROUND

In the chip packaging process in the prior art, for example, the fan-out packaging structure is a wafer that is artificially reconstructed, and the reconstructed wafer contains plastic, silicon and metal materials, wherein the volume edge and the thermal expansion coefficient between silicon and plastic are different in each direction of X, Y, Z, which all cause the warping phenomenon of the packaging body due to the effect of thermal expansion and contraction when the process is heated or cooled.

### SUMMARY OF THE INVENTION

Therefore, the present application provides a fan-out packaging structure for a chip to reduce the warping deformation of the packaging body.

According to a first aspect, an embodiment of the present application provides a fan-out packaging structure for a chip, at least comprising: a first chip and a second chip with oppositely fitted bottoms; a plurality of metal terminals, which are distributed around the first chip, one side of the metal terminal being on a same plane with a front side of the first chip; a lead, which is connected between a front side of the second chip and the other side of the metal terminal; a packaging layer, which packages the first chip, the second chip, the lead and the metal terminals and has a first surface and a second surface opposite to the first surface, the first surface and one side of the metal terminal being in a same plane as the front side of the first chip; a lead-out layer, which is arranged on the first surface of the packaging layer and is electrically connected with one side of the metal terminal and the front side of the first chip respectively.

Optionally, the lead-out layer comprises a first wiring layer, which is formed on the first surface of the packaging layer and is electrically connected with the front side of the first chip and one side of some metal terminals.

Optionally, the lead-out layer further comprises: a dielectric layer, which is arranged on a surface of the first wiring layer and is provided with a plurality of vias; a second wiring layer, which is arranged on the surface of the dielectric layer and is electrically connected with at least one of the first wiring layer, one side of the metal terminal and the front side of the first chip respectively through the via.

Optionally, the lead-out layer further comprises: a pin, which is distributed on the second wiring layer.

Optionally, the first surface of the packaging layer exposes one side of the metal terminal and the front side of the first chip.

Optionally, the packaging layer comprises a plastic sealing layer.

Optionally, any one of a soldering layer, a sintering layer or an adhesive layer is provided between the first chip and the second chip.

According to a second aspect, an embodiment of the present application provides a fan-out packaging method for a chip, comprising: providing a carrier plate; sequentially mounting a flip chip as a first chip and a formal chip as a second chip on the carrier plate in a stacking manner; arranging a plurality of metal terminals around the first chip; connecting a lead between a front side of the second chip and a corresponding metal terminal; forming a packaging layer on the carrier plate to package the first chip, the second chip, the lead, and the metal terminals; removing the carrier plate and forming a lead-out layer on a side the packaging layer from which the carrier plate is removed.

Optionally, removing the carrier plate and forming a lead-out layer on a side of the packaging layer from which the carrier plate is removed comprises: removing the carrier plate and forming a first wiring layer on the side of the packaging layer from which the carrier plate is removed; forming a dielectric layer on the first wiring layer; forming a via on the dielectric layer; forming a second wiring layer on the dielectric layer, and electrically connecting with at least one of the first wiring layer, one side of the metal terminal and the front side of the first chip through the via; and forming a plurality of pins at corresponding positions on the second wiring layer.

Optionally, forming a packaging layer on the carrier plate comprises: forming a packaging layer in the areas where the first chip, the second chip and the metal terminals are located in an injection molding mode.

The technical solution of the present application has the following advantages:

Compared with the fan-out packaging structure for packaging with a carrier plate in the prior art, a plurality of metal terminals are distributed. On one hand, the metal terminals are small in size, the volume ratio of metal terminals is used to balance the packaging layer, for example, the thermal expansion coefficient of material of a plastic sealing structure is used, the numeric value of the equivalence coefficient of thermal expansion of the packaging body is reduced to control the warping of the product and reducing the possibility of deformation and warping during packaging. And a plurality of metal terminals can be used as a bridge for signal interconnection to realize signal interconnection of multiple chips stacked in a Z direction.

### BRIEF DESCRIPTION OF THE DRAWINGS

In order to more clearly illustrate the specific embodiments of the present application or the technical solutions in the prior art, the accompanying drawings used in describing the embodiments or the prior art will be briefly introduced below, and apparently, the accompanying drawings mentioned in the following description are just some embodiments of the present application, and other drawings can be derived by a person skilled in the art from these drawings without expenditure of creative efforts.

FIG. 1 is a structural diagram of a cross-sectional example of a fan-out packaging structure for a chip according to an embodiment of the present application;

FIGS. 2-10 are specific flow diagrams of a packaging method of a fan-out packaging method for a chip according to embodiments of the present application.

Reference numerals are as follows:

10—first chip; 20—second chip; 30—metal terminal; 40—lead; 50—packaging layer; 60—lead-out layer; 61—first wiring layer; 62—dielectric layer; 63—via; 64—second wiring layer; 65—pin; 100—carrier plate.

### DETAILED DESCRIPTION OF EMBODIMENTS

The technical solutions of the present application will be described clearly and completely in conjunction with the accompanying drawings. Apparently, the described embodiments are only a part of, but not all of, the embodiments of the present application. All other embodiments obtained by a person skilled in the art based on the embodiments described in the present application without expenditure of creative efforts belong to the protection scope of the present application.

In addition, the technical features mentioned in different embodiments of the present application described below can be combined with each other as long as they do not conflict with each other.

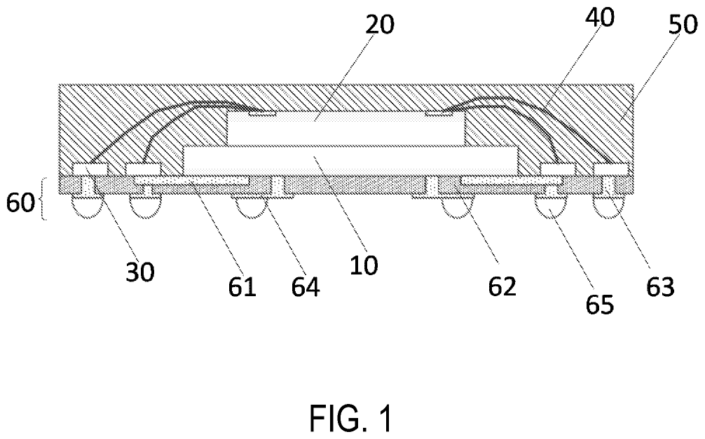

An embodiment of the present application provides a fan-out packaging structure for a chip, as shown in FIG. 1, the structure comprises: a first chip 10 and a second chip 20 with oppositely fitted bottoms; a plurality of metal terminals 30, which are distributed around the first chip 10, one side of the metal terminal 30 being on a same plane with a front side of the first chip 10; a lead 40, which is connected between a front side of the second chip 20 and the other side of the metal terminal 30; a packaging layer 50, which packages the first chip 10, the second chip 20, the lead 40 and the metal terminals 30 and has a first surface and a second surface opposite to the first surface, the first surface and one side of the metal terminal 30 being in a same plane as the front side of the first chip 10; in the present embodiment, the packaging layer 50 comprises a plastic sealing layer, the first chip 10, the second chip 20, the metal terminal 30 and the lead 40 are packaged by a plastic sealing process; a lead-out layer 60, which is arranged on the first surface of the packaging layer 50 and is electrically connected with one side of the metal terminal 30 or the front side of the first chip 10 respectively.

Compared with the fan-out packaging layer 50 for packaging with a carrier plate 100 in the prior art, the fan-out packaging structure for a chip provided by the present embodiment adopts a plurality of distributed arranged metal terminals 30. On one hand, the volume ratio of metal terminals 30 is used to balance the packaging layer 50, for example, the thermal expansion coefficient of material of a plastic sealing structure is used, the structure reduces the numeric value of the equivalence coefficient of thermal expansion of the packaging body, thereby controlling the warping of the product and reducing the possibility of deformation and warping during packaging. And a plurality of metal terminals 30 can be used as a bridge for signal interconnection to realize signal interconnection of multiple chips stacked in a Z direction.

In the present embodiment, the first chip 10 and the second chip 20 can be stacked in such a manner that the bottoms are oppositely fitted, in addition, as an optional embodiment, a plurality of chips may be comprised, the bottoms of the first chip 10 and the second chip 20 are oppositely fitted, a transition layer is arranged on the second chip 20, which does not cover the front bonding pad of the second chip 20, the front bonding pads of the second chip 20 and the third chip are connected to the metal terminal 30 through the lead 40, and a space of lead 40 can be reserved between the second chip 20 and the third chip. And a plurality of chips can be stacked in this way. In the present embodiment, the first chip 10 and the second chip 20 can be connected by conductive adhesive bonding, solder welding or sintering, and the second chip 20 and the third chip can also be connected by conductive adhesive bonding, solder welding or sintering.

As an alternative embodiment, the lead-out layer 60 comprises a first wiring layer 61, which is formed on the first surface of the packaging layer 50 and is electrically connected with the front side of the first chip 10 and one side of some metal terminals 30. The first surface of the packaging layer 50 exposes one side of the metal terminal 30 and the front side of the first chip 10. The first wiring layer 61 can realize the interconnection between the metal terminal 30 and the front side of the first chip 10 to fan out the bonding pad of the first chip 10, increase the fan-out area, and reduce the value of the equivalent thermal expansion coefficient of the packaging body, thereby controlling the warping of the product and reducing the possibility of deformation and warping during packaging.

As an alternative embodiment, the lead-out layer 60 further comprises: a dielectric layer 62, which is arranged on a surface of the first wiring layer and is provided with a plurality of vias 63; a second wiring layer 64, which is arranged on the surface of the dielectric layer 62 and is electrically connected with at least one of the first wiring layer 61, one side of the metal terminal 30 and the front side of the first chip 10 respectively through the via 63. In the present embodiment, the dielectric layer 62 can be an organic dielectric material such as poly-p-phenylene benzobisoxazole (PBO), polyimide material and so on.

A via 63 corresponding to the first wiring layer 61, the metal terminal 30 and the front bonding pad of the first chip 10 is provided on the dielectric layer 62. The second wiring layer 64 can be formed on the surface of the via 63 and the dielectric layer 62 by electroplating, sputtering and other processes to realize electrical connection with the first wiring layer 61, one side of the metal terminal 30 and the front side of the first chip 10. In the present embodiment, the second wiring layer 64 is provided with a pin 65, which can be a ball pin or a stud pin.

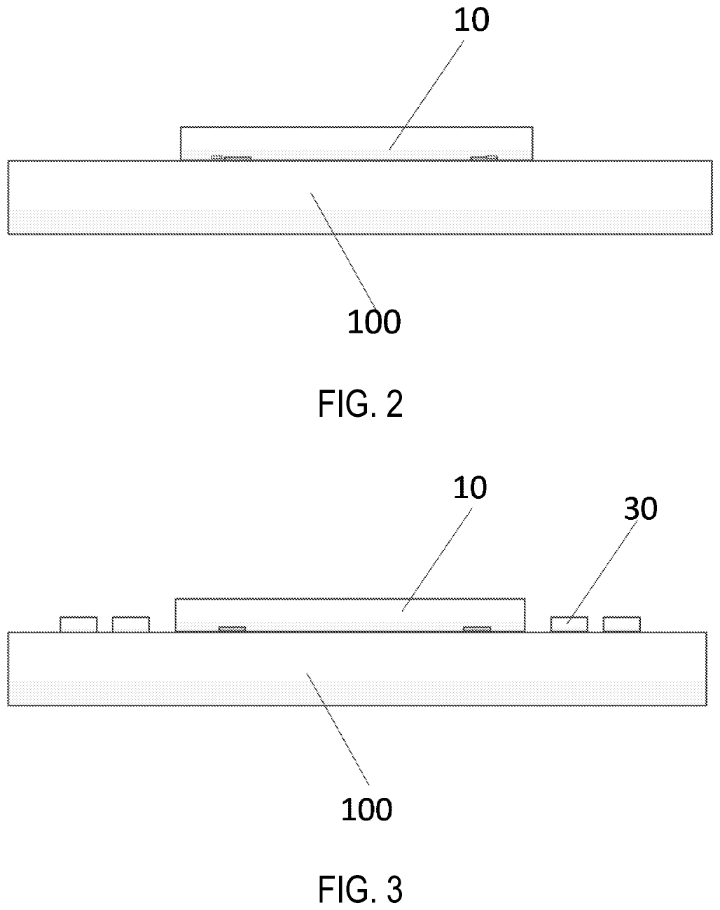

The present embodiment provides a fan-out packaging method for a chip, and a manufacturing process of the packaging structure will be described in detail in conjunction with FIGS. 2-10, wherein, the manufacturing method of the packaging structure may comprise the following steps:

Step S1: providing a carrier plate 100, the carrier plate 100 has a first surface and a second surface opposite to the first surface, and the first chip 10 is flip mounted in a stacking manner on the first surface.

In the present embodiment, the carrier plate 100 can be a silicon substrate or a glass substrate, and in the present embodiment, the first chip 10 can be flip mounted on the first surface of the carrier plate 100 in the form of bonding. The structure shown in FIG. 2 is formed by performing step S1.

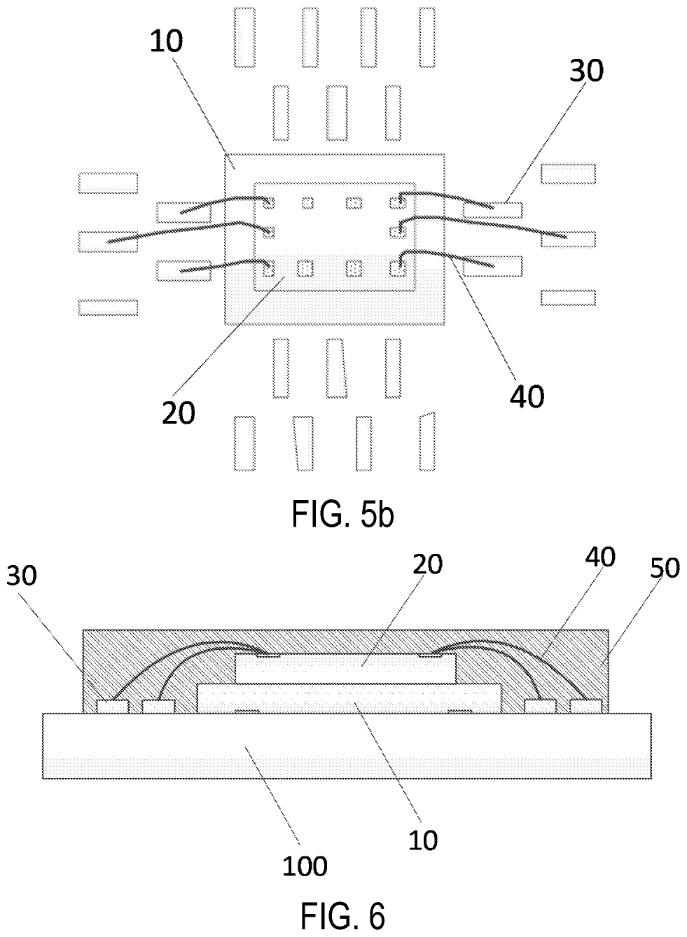

Step S2: arranging a plurality of metal terminals 30 around the first chip 10. In the present embodiment, the metal terminals 30 can be flip mounted on the first surface of the carrier plate 100 in the form of bonding. The structure shown in FIG. 3 is formed by performing step S2, the distribution diagram of metal terminal 30 can be seen as shown in FIG. 5b.

Step S3: the second chip 20 is formal mounted on the back side of the first chip 10.

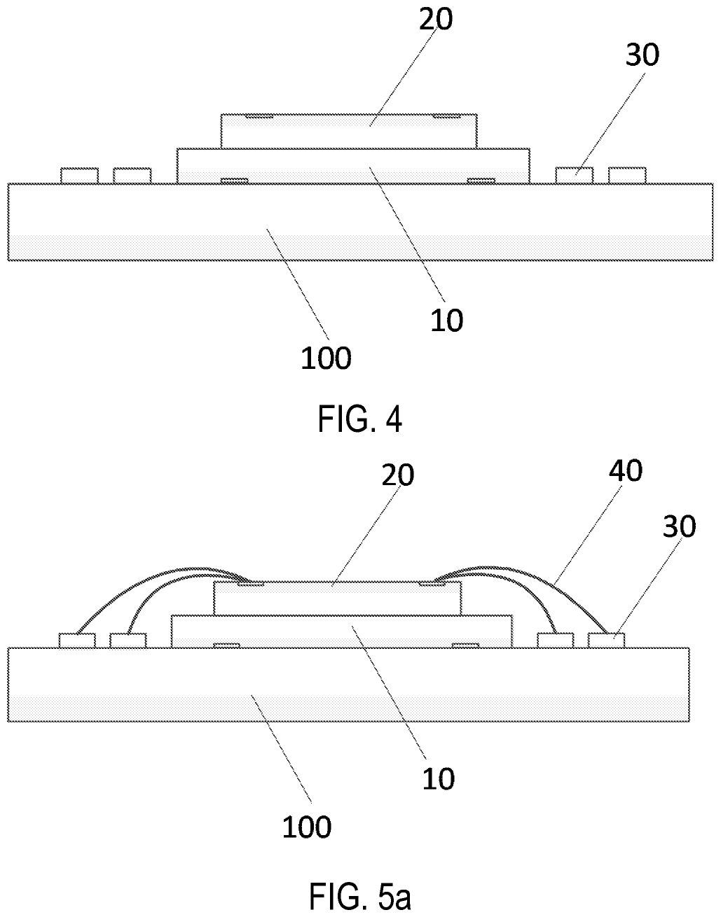

In the present embodiment, the second chip 20 can be fixedly mounted on the back side of the first chip 10 of the carrier plate 100 in fixing ways such as conductive adhesive bonding, solder welding, sintering, etc. In other embodiments, other fixing ways can be used. The structure shown in FIG. 4 is, but not limited to, a structure with one formal chip fixedly mounted. In other embodiments, a plurality of chips can also be fixedly mounted according to the actual application. Wherein, step S2 and step S3 can be interchanged in sequence.

Step S4: connecting a lead 40 between a front side of the second chip 20 and a corresponding metal terminal 30.

In the present embodiment, the lead 40 can be bonded between the front side of the second chip 20 and the corresponding metal terminal 30 by bonding the lead 40. The chip and the carrier plate 100 are interconnected by the lead 40 to form the structure shown in FIG. 5a and FIG. 5b, which can avoid the influence of the offset formed when the chip is mounted to the carrier 100, so that the accuracy of the subsequent photolithography process is higher.

Step S5: forming a packaging layer 50 on the carrier plate 100 to package the first chip 10, the second chip 20, the lead 40, and the metal terminals 30, the carrier plate 100.

In the present embodiment, the structure shown in FIG. 6 is formed by performing step S4. The material of the packaging layer can be, but is not limited to, epoxy resin. In other embodiments, it can be other plastic sealing materials.

S6: removing the carrier plate 100 and forming a lead-out layer 60 on a side the packaging layer 50 from which the carrier plate 100 is removed. Thereby a fan-out package for the chip as shown in FIG. 10 is formed. Specifically, it can comprise the following steps:

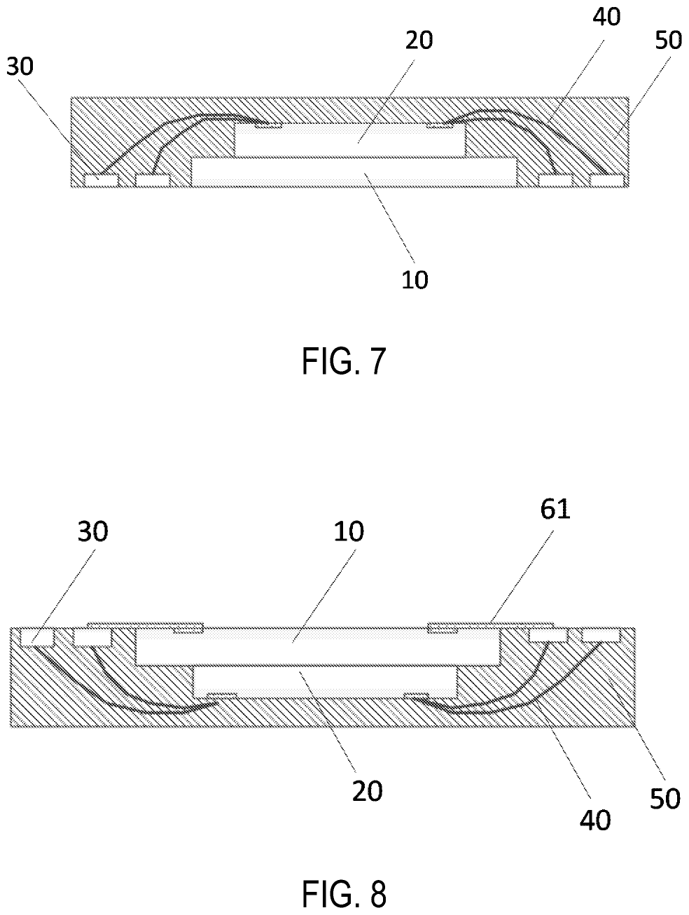

S61, removing the carrier plate 100; the structure shown in FIG. 7 is formed after step S61 is performed;

S62, forming a first wiring layer 61 on the side of the packaging layer 50 from which the carrier plate 100 is removed; in the present embodiment, the first wiring layer 61 can be manufactured by a standard wafer process such as photolithography, sputtering, electroplating, and the like, to realize the interconnection between the first chip 10 and the metal terminal 30. Specifically, the structure shown in FIG. 8 is formed after step S62 is performed.

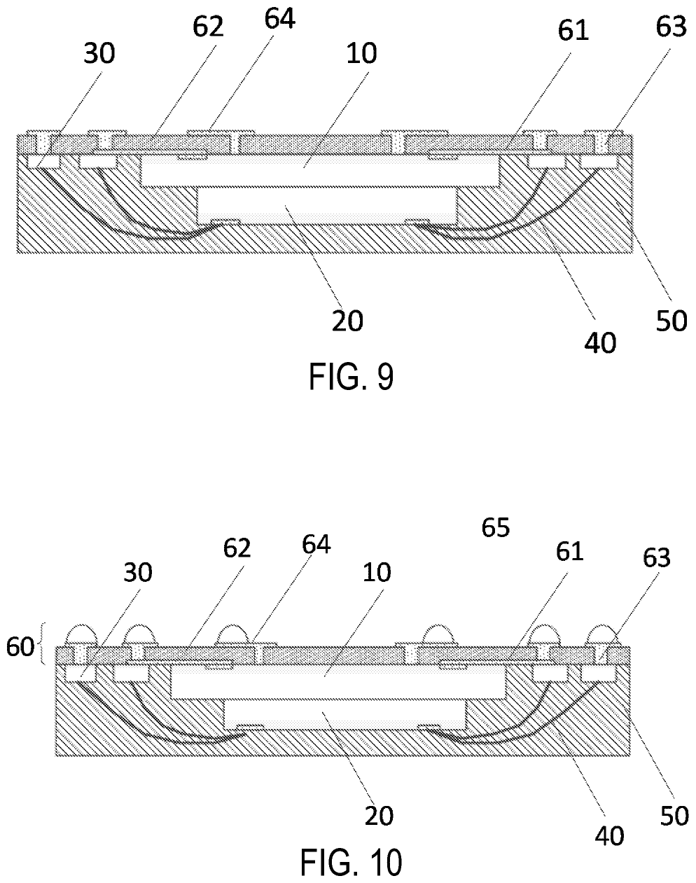

S63, forming a dielectric layer 62 on the first wiring layer 61, and forming a via 63 on the dielectric layer 62, and then forming a second wiring layer 64 on the dielectric layer 62, and electrically connecting with at least one of the first wiring layer 61, one side of the metal terminal 30 and the front side of the first chip 10 through the via 63; in the present embodiment, the dielectric layer 62 can be formed by spin-coating a PI/PBO type organic dielectric material, and the via 63 can be formed by photolithography or laser punching. Specifically, the structure shown in FIG. 9 is formed after step S63 is performed.

S64: forming a plurality of pins 65 at corresponding positions on the second wiring layer 64. Specifically, a ball can be implanted at a corresponding position on the second wiring layer 64 to form a pin. In an alternative embodiment, a stud pin may also be implanted on the second wiring layer. Specifically, the structure shown in FIG. 10 is formed after step S64 is performed.

In the present embodiment, compared with the fan-out packaging layer 50 for packaging with a carrier plate 100 in the prior art, by performing steps S1 to S6 of the manufacturing method of the fan out packaging layer 50 of the chip, a plurality of metal terminals 30 are distributed. On one hand, the volume ratio of metal terminals 30 is used to balance the packaging layer 50, for example, the thermal expansion coefficient of material of a plastic sealing structure is used, the numeric value of the equivalence coefficient of thermal expansion of the packaging body is reduced to control the warping of the product and reducing the possibility of deformation and warping during packaging. And a plurality of metal terminals 30 can be used as a bridge for signal interconnection to realize signal interconnection of multiple chips stacked in a Z direction.

It should be understood that the above embodiments are only for clarity of illustration and are not intended to limit the embodiments. Other variations and modifications will be apparent to a person skilled in the art in light of the above description. This need not be, nor should it be exhaustive of all embodiments. And obvious variations or modifications can be made without departing from the scope of the present invention.

1. A fan-out packaging structure for a chip, comprising:
a first chip and a second chip with oppositely fitted bottoms;
a plurality of metal terminals, which are distributed around the first chip, one side of the metal terminal being on a same plane with a front side of the first chip;
a lead, which is connected between a front side of the second chip and the other side of the metal terminal;
a packaging layer, which packages the first chip, the second chip, the lead and the metal terminals and has a first surface and a second surface opposite to the first surface, the first surface and one side of the metal terminal being in a same plane as the front side of the first chip;
a lead-out layer, which is arranged on the first surface of the packaging layer and is electrically connected with one side of the metal terminal and/or the front side of the first chip respectively.

2. The fan-out packaging structure for a chip according to claim 1, wherein the lead-out layer comprises a first wiring layer, which is formed on the first surface of the packaging layer and is electrically connected with the front side of the first chip and one side of some metal terminals.

3. The fan-out packaging structure for a chip according to claim 2, wherein the lead-out layer further comprises:
a dielectric layer, which is arranged on a surface of the first wiring layer and is provided with a plurality of vias;
a second wiring layer, which is arranged on the surface of the dielectric layer and is electrically connected with at least one of the first wiring layer, one side of the metal terminal and the front side of the first chip respectively through the via.

4. The fan-out packaging structure for a chip according to claim 3, wherein the lead-out layer further comprises:
a pin, which is distributed on the second wiring layer.

5. The fan-out packaging structure for a chip according to claim 1, wherein the first surface of the packaging layer exposes one side of the metal terminal and the front side of the first chip.

6. The fan-out packaging structure for a chip according to claim 5, wherein the packaging layer comprises a plastic sealing layer.

7. The fan-out packaging structure for a chip according to claim 1, wherein any one of a soldering layer, a sintering layer or an adhesive layer is provided between the first chip and the second chip.

8. A fan-out packaging method for a chip, comprising:
providing a carrier plate;
sequentially mounting a flip chip as a first chip and a formal chip as a second chip on the carrier plate in a stacking manner;
arranging a plurality of metal terminals around the first chip;
connecting a lead between a front side of the second chip and a corresponding metal terminal;
forming a packaging layer on the carrier plate to package the first chip, the second chip, the lead, and the metal terminals;
removing the carrier plate and forming a lead-out layer on a side the packaging layer from which the carrier plate is removed.

9. The fan-out packaging method for a chip according to claim 8, wherein removing the carrier plate and forming a lead-out layer on a side of the packaging layer from which the carrier plate is removed comprises:
removing the carrier plate and forming a first wiring layer on the side of the packaging layer from which the carrier plate is removed;
forming a dielectric layer on the first wiring layer;
forming a via on the dielectric layer;
forming a second wiring layer on the dielectric layer, and electrically connecting with at least one of the first wiring layer, one side of the metal terminal and the front side of the first chip through the via; and forming a plurality of pins at corresponding positions on the second wiring layer.

10. The fan-out packaging method for a chip according to claim 8, wherein forming a packaging layer on the carrier plate comprises:
forming a packaging layer in the areas where the first chip, the second chip and the metal terminals are located in an injection molding mode.
